(19) United States
(12) Patent Application Publication
(10) Pub. No.: US 2004/0201968 A1
(43) Pub. Date: Oct. 14, 2004

(54) Multi-bank memory module

(76) Inventor: Eric Tafolla, Irvine, CA (US)

Correspondence Address: CHARLES C.H. WU, 7700 IRVINE CENTER DRIVE, SUITE 710, IRVINE, CA, 92618-3043, US

(21) Appl. No.: 10/410,721

(22) Filed: Apr. 9, 2003

(51) Int. Cl. H05K 1/14

(52) U.S. Cl. 361/736

(57) ABSTRACT

A memory module for a computer system comprises a printed circuit board adapted for the computer system. The memory module further comprises four banks of memory chips mounted upon the printed circuit board. Each of the four banks of memory has a separate chip select signal and clock enable signal routed to it. The combination of four chip select and four clock enable signals allows for activation of any of the four banks of memory chips.

### BACKGROUND OF THE INVENTION

1. Field of the Invention

The invention relates in general to memory hardware for computer systems. More particularly, this invention relates to memory modules for expanding memory and reducing costs in computer systems.

2. Description of the Related Art

Modern personal computers (PCs) allow for memory expansion by way of expansion sockets for memory modules. Memory modules are slim circuit boards that hold Dynamic Random Access Memory (DRAM) chips. Memory modules can be plugged into the sockets of a computer's motherboard, increasing the memory capacity of the PC.

Memory modules, typically 3 to 4 inches in length and ¾-inch in height, contain a small printed-circuit board called a substrate. DRAM chips, commonly packaged in inexpensive surface-mount packages, are applied directly on the substrate. Other surface mounted components are soldered onto one or both surfaces of the substrate.

Although most memory modules are similar in size, they come in different pin count configurations. Originally, pins counts represented the number of pins extending from the end of a memory module. Today, memory modules are leadless, with pin counts representing the conductive contacts found at one edge of the module. Sample pin count values include 144, 168, 184, and 200.

DRAM chips may contain different amounts of memory. As manufacturing costs decrease, DRAM chips with smaller memory tend to cost substantially less than DRAM chips with more memory. In most instances, two DRAM chips, each with memory half the size of one larger DRAM chip, cost less than the larger DRAM chip.

To access a location in a DRAM mounted on a memory module, an address must be specified to address inputs. The address is then decoded, and data from this address can be decoded.

Total memory capacity is limited by the number of address inputs on the memory chips employed by the system. This is true even if the system address bus is wider than the number of address inputs for an individual memory chip. Memory chips with a greater number of address inputs, and hence higher capacity, may disproportionately increase the cost of the desired memory expansion.

Therefore, the need arises for allowing extra banks of memory to be added to a computer system. By having multiple memory banks, a computer system's memory can be increased without having to change the type of memory employed. In addition, the use of multiple memory banks can save costs by substituting a larger quantity of DRAM chips with smaller memory capacity for a smaller quantity of DRAM chips with more memory.

In U.S. Pat. No. 6,414,868, Wong discloses a memory expansion module including multiple memory banks and a bank control circuit. In one embodiment, a memory module includes a printed circuit board with a connector edge adapted for insertion in an expansion socket of a computer system. Mounted upon the circuit board is a plurality of memory chips, typically Dynamic Random Access Memory (DRAM) chips, which make up an upper bank and a lower bank of memory. A buffer circuit is mounted upon the printed circuit board, for the purpose of driving address signals, Column Address Strobe (CAS) signals, and write enable signals to each of the memory chips. Also mounted upon the printed circuit board is a bank control circuit, which is coupled to the memory chips. An address signal is used as a bank selection input to the bank control circuit, which will drive Row Address Strobe (RAS) signals to the memory chips of the selected memory bank. The bank control circuit is further configured to drive RAS signals to both banks simultaneously during CBR (CAS before RAS) refresh operations, which occur when a CAS signal is asserted before a RAS signal. The subject invention, on the other hand, uses two additional chip select and two additional clock enable signals to allow for access to multiple memory banks.

### SUMMARY OF THE INVENTION

Accordingly, one object of the present invention is to provide a memory module with increased memory. A second object of the invention is to provide a memory module with decreased manufacturing cost.

A third object of the invention is to provide a memory module with multiple banks of memory chips.

A fourth object of the invention is to provide a memory module capable of accessing four banks of memory chips in a single computer memory expansion slot.

To achieve these and other advantages and in accordance with the purpose of the invention, as embodied and broadly described herein, the invention provides a memory module for a computer system comprising a printed circuit board adapted for the computer system. The memory module further comprises four banks of memory chips mounted upon the printed circuit board. Each of the four banks of memory has a separate chip select signal and clock enable signal routed to it. The combination of four chip select and four clock enable signals allows for activation of any of the four banks of memory chips.

### BRIEF DESCRIPTION OF THE DRAWINGS

FIG. 1 is a block diagram illustrating a computer system with memory modules.

FIG. 2 is a diagram illustrating components associated with an embodiment of a multi-bank memory module;

FIG. 3 is a diagram illustrating components associated with an embodiment of a multi-bank memory module in which the memory chips are stacked;

FIG. 4 is a diagram illustrating components associated with an embodiment of a multi-bank memory module in which the memory chips span more than one printed circuit board;

FIGS. 5A and 5B combine to form a block diagram illustrating the electrical connections associated with an embodiment of the invention.

### DESCRIPTION OF THE PREFERRED EMBODIMENTS

Before proceeding with a description of the method and apparatus of the present invention, a brief summary of chip select and enable signals is provided.

Every memory chip has an input called chip select. To activate the chip, a value of 0 is sent to this input because it uses negative logic. If there is a value of 1 on the wire connected to this input, the chip is inactive.

Some memory chips also have an enable input. Chips of this type must receive a value of 1 on this input and a value of 0 on the chip select input to be active. The ability to activate and deactivate memory chips using chip select and enable signals allows for selection of the correct chip for a particular memory address. Industry standard memory uses two chip select and two chip enable signals to access chips spanning two memory banks.

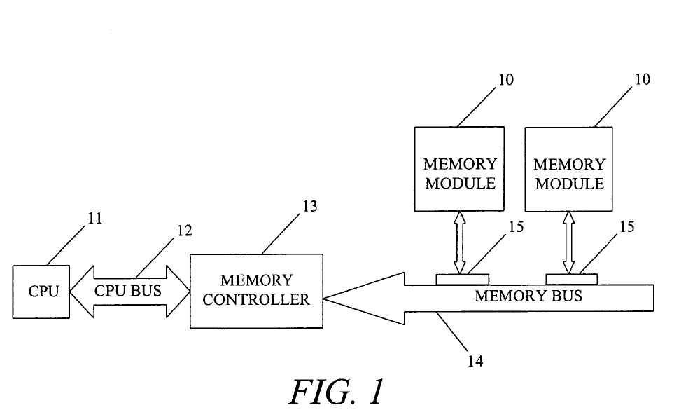

Referring now to FIG. 1, a computer system employing one embodiment of memory modules 10 is shown. The computer system includes a CPU 11 connected to a memory controller 13 via a CPU bus 12. Memory controller 13 couples to memory modules 10 through memory bus 14. Each of the memory modules 10 connects to memory bus 14 via expansion sockets 15. Memory modules 10 expand the main memory of the computer system.

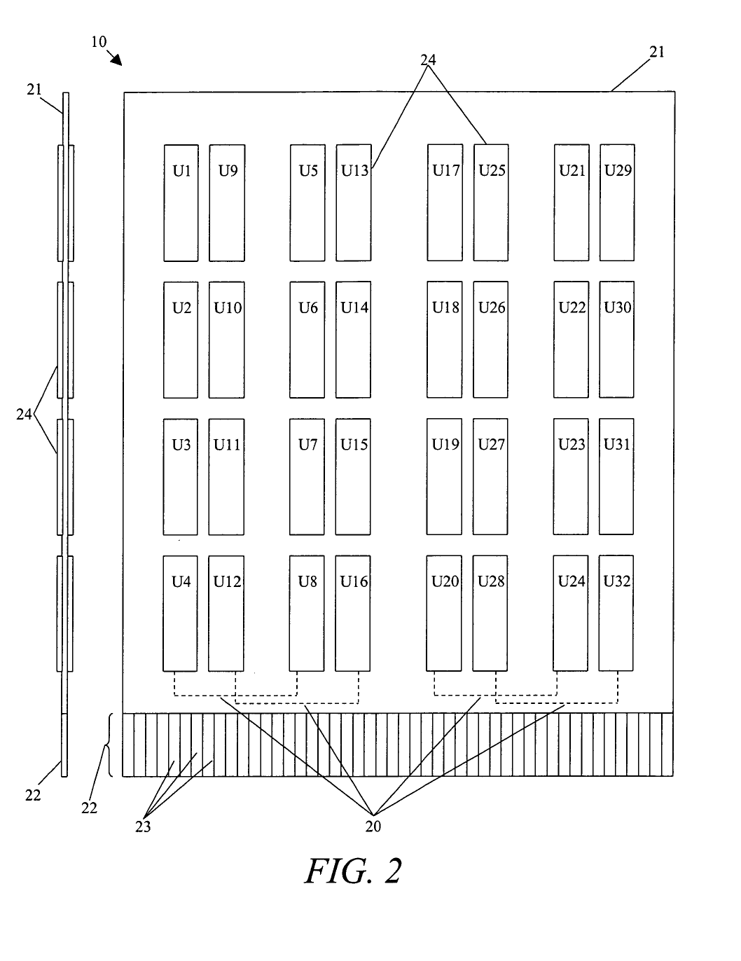

With reference to FIG. 2, a diagram illustrating components associated with an embodiment of a multi-bank memory module 10 is shown. Memory chips 24 are mounted upon printed circuit board 21. In this embodiment, memory chips 24 are labeled U1 to U32 and are arranged in a single level. Memory chips 24 are typically DRAM chips. However, other memory chips such as SDRAM chips may be used. Memory chips 24 are grouped upon printed circuit board 21 as memory banks 20. In this embodiment, four memory banks 20 are mounted upon printed circuit board 21.

Still referring to FIG. 2, an edge connector 22 connects memory module 10 to CPU 11 of FIG. 1. On one end, edge connector 22 connects to expansion socket 15, which in turn connects to memory bus 14, memory controller 13, CPU bus 12, and finally to CPU 11 as shown in FIG. 1. On the other end, pins 23 on edge connector 22 couple to etchings placed on printed circuit board 21. The etchings (not shown) send various signals to and from memory chips 24. Signals passing through edge connector 22 include data signals, address signals, and control signals. Typical counts for the number of pins 23 on edge connector 22 include 144, 168, 184, and 200.

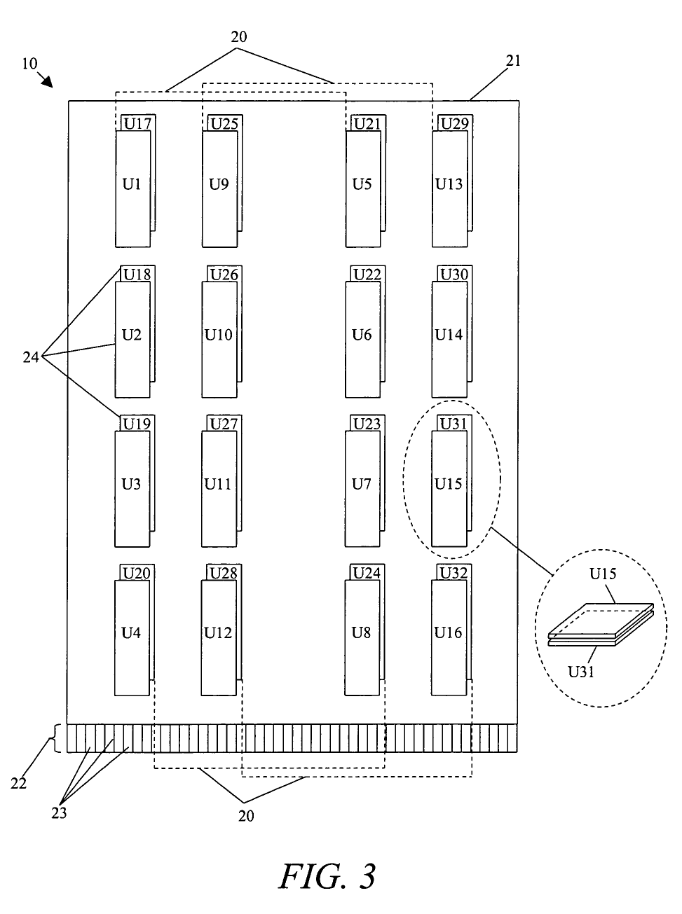

Referring now to FIG. 3, a diagram illustrating components associated with an alternative embodiment of a multi-bank memory module is shown. Memory chips ranging from U1 to U32 are located on printed circuit board 21. In this embodiment, memory chips 24 are stacked upon each other. Stacking increases the density of memory chips 24 on printed circuit board 21. Typically, each of the input/output data terminals, power and ground terminals of memory chips 24 are connected in parallel. In this embodiment, two stacks of memory chips 24 are mounted upon printed circuit board 21. However, the number of stacks need not be two. In addition, the invention is equally applicable with different configurations of stacked memory chips 24 on printed circuit board 21.

Still referring to FIG. 3, memory chips 24 are grouped upon printed circuit board 21 as memory banks 20. Four memory banks 20 are mounted upon printed circuit board 21. Printed circuit board 21 has an edge connector 22 with pins 23 connecting memory module 10 to expansion socket 15 as seen in FIG. 1.

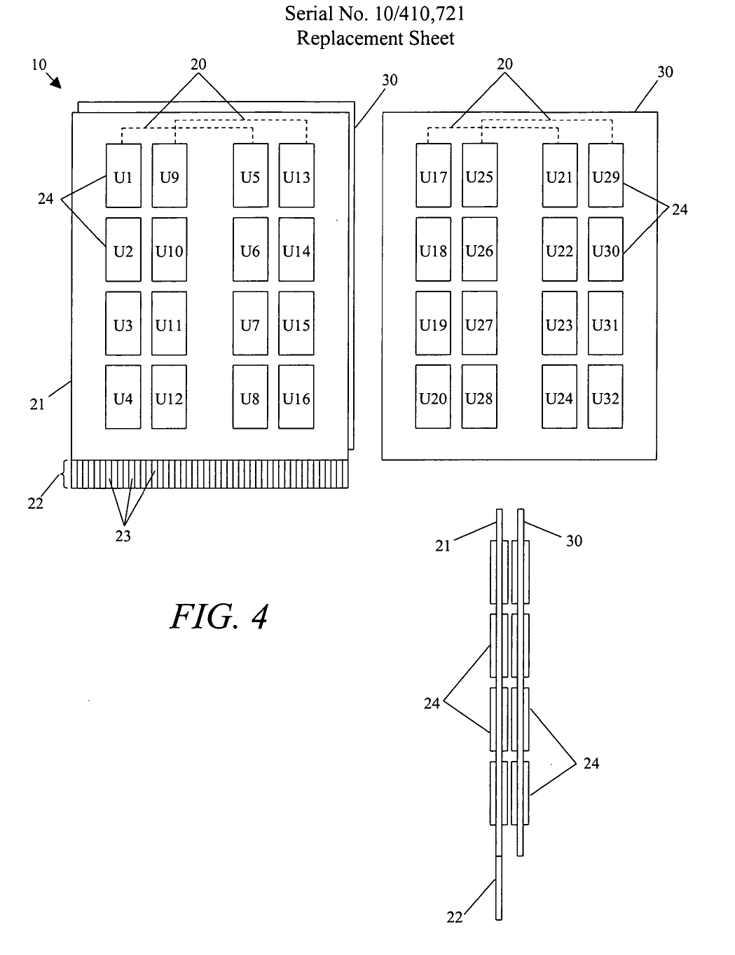

Referring now to FIG. 4, a diagram illustrating components associated with an embodiment of a multi-bank memory module in which memory chips 24 span more than one printed circuit board. In this embodiment, memory chips 24 span two printed circuit boards 21 and 30. However, the number of printed circuit boards should not be limited to two. In addition, the invention is equally applicable with different configurations of stacked memory chips 24 on the set of printed circuit boards.

Still referring to FIG. 4, the memory chips ranging from U1 to U16 mount upon printed circuit board 21, and the memory chips ranging from U17 to U32 are located on printed circuit board 30. Printed circuit board 21 has an edge connector 22 with pins 23 connecting memory module 10 to expansion socket 15 as seen in FIG. 1. Printed circuit boards 21 and 30 are electrically connected to each other via conductive pads (not shown) connecting the two boards. Although this embodiment uses conductive pads to connect a set of printed circuit boards to a common connector edge, any means for sharing the connector edge may be used. For example, a PCB ribbon cable with electrical connections may be employed.

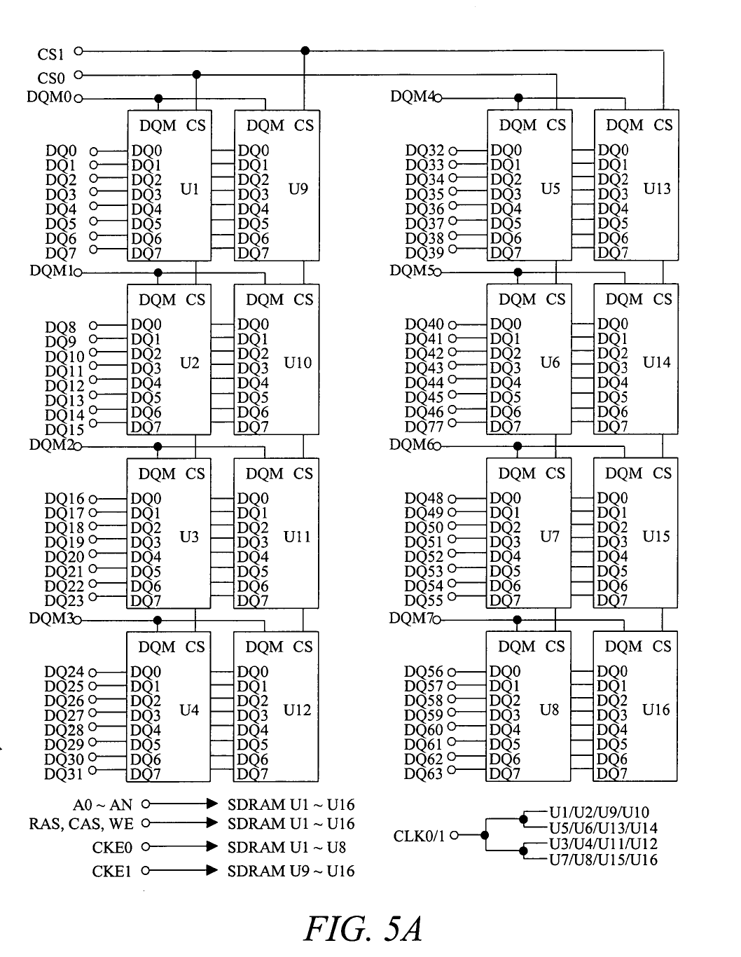

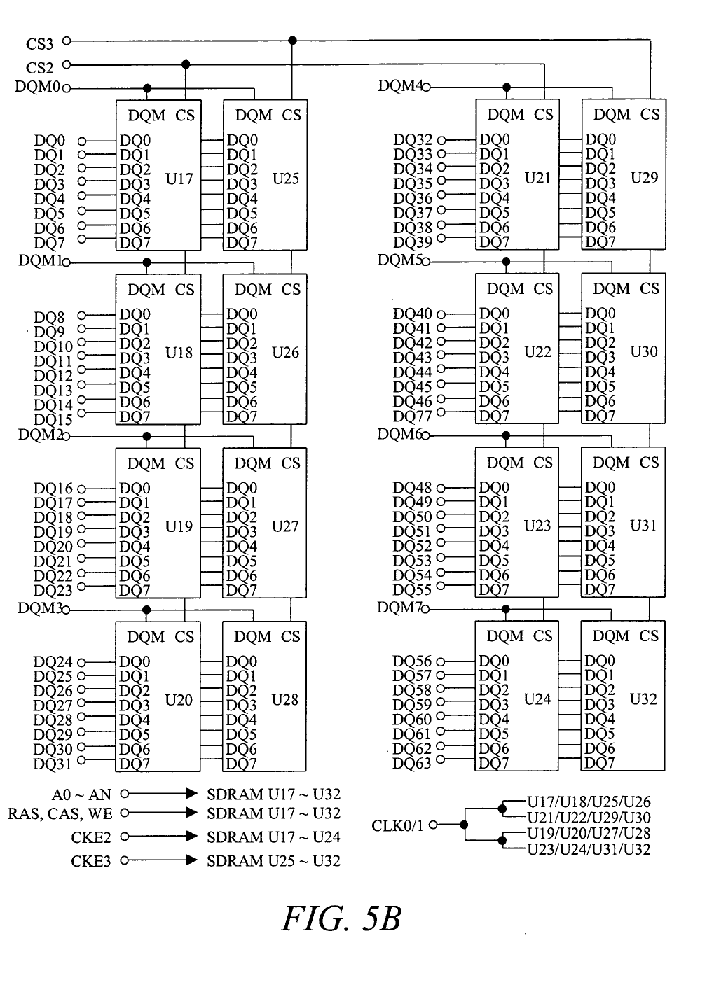

FIGS. 5A and 5B combine to form a block diagram illustrating the electrical connections associated with an embodiment of the invention. FIG. 5A illustrates the electrical connections to memory chips U1 to U16. FIG. 5B, on the other hand, illustrates the electrical connections for memory chips U17 to U32. In accessing a specified address in memory, memory module 10 first determines which of the memory banks 20 is being addressed. After determining the correct memory bank, the specified memory address can be accessed from a particular memory chip 24.

Referring now to FIG. 5A, a diagram illustrating the electrical connections to memory chips U1 to U16 is shown. In accessing a specified memory address, chip select signals CS0 and CS1 are used to activate different memory banks 20. Chip select signals CS0 and CS1 each connect to one of the pins 23 shown in FIGS. 2, 3 and 4. The chip select signals disable or enable device operation by masking or enabling all inputs except clock input (CLK), clock enable input (CKE) and data input/output mask (DQM). In this example, sending a value of 0 to CS0 enables the memory bank with chips ranging from U1 to U8. Sending a value of 0 to CS1, on the other hand, enables the memory bank with chips U9 to U16.

In addition to using chip select signals, memory module 10 uses clock enable signals CKE0 and CKE1 to activate different memory banks. Clock enable signals CKE0 and CKE1 mask the system clock to freeze operation from the next clock cycle. Clock enable signal CKE0 enables and disables the memory bank with chips U1 to U8 while clock enable signal CKE1 enables and disables the memory bank with chips U9 to U16. By using a combination of two chip select signals and two clock enable signals, memory module 10 can activate two of the four memory banks.

Referring now to FIG. 5B, a diagram illustrating the electrical connections to memory chips U17 to U32 is shown. As stated earlier, conventional memory modules only use two chip select signals. In addition, most memory modules have unused pins 23. Memory module 10 assigns two of the unused pins to two additional chip select signals CS2 and CS3. These chip select signals access the two remaining memory banks. Sending a value of 0 to CS2 enables the memory bank with chips ranging from U17 to U24. Sending a value of 0 to CS3 enables the memory bank with chips ranging from U25 to U32.

Clock enable signals CKE2 and CKE3 work in a similar manner, using two additional unused pins 23. CKE2 activates the bank with chips U17 to U24, while CKE3 accesses the memory bank with chips U25 to U32. By using the two additional chip select and clock enable signals, memory module 10 can activate a total of four memory banks.

Once a memory bank is selected, memory module 10 uses address signals A0 thru AN to access the specified memory address. Each address signal is routed to a pin 23 on connector edge 22. Row and column addresses are multiplexed on the same pins using row address strobe RAS and column address strobe CAS. Data is written or read at the specified address via data signals DQ0 to DQ63. Each data signal is routed to a pin 23 on connector edge 22. Data input and output is multiplexed using the data input/output mask signals DQM0 to DQM7. Write enable WE enables write operation.

In summary, memory module 10 introduces two additional chips select lines and two additional clock enable signals. The additional signals are routed to memory module 10 via unused pins 23 on the edge connector 22. By doing this, memory module 10 can access four, as opposed to two, memory banks in a single expansion socket 15.

Other embodiments of the invention will appear to those skilled in the art from consideration of the specification and practice of the invention disclosed herein. For example, while the present invention has been described as applicable to a memory module including DRAM or SDRAM devices, any assembly of memory devices forming a single memory module may be employed. Also, while the memory modules have described as mounted upon one or two printed circuit boards, the invention is equally applicable to any assembly of memory chips spanning multiple printed circuit boards. In addition, any conducting means for connecting the contact pins of the edge connector to the memory banks and memory chips may be used. It is intended that the specification and examples to be considered as exemplary only, with a true scope and spirit of the invention being indicated by the following claims. amendments to the claims

1. A memory module for a computer system comprising:
a printed circuit board;
a first, second, third and fourth bank of memory chips mounted upon said printed circuit board;
a first chip select signal and a first clock enable signal routed to said printed circuit board, for activating said first bank of memory chips;
a second chip select signal and a second clock enable signal routed to said printed circuit board, for activating said second bank of memory chips;
a third clock enable signal routed to said printed circuit board, for activating said third bank of memory chips; and
a fourth chip select signal and a fourth clock enable signal routed to said printed circuit board, for activating said fourth bank of memory chips.

2. The memory module according to claim 1 wherein said printed circuit board has a connector edge for connecting to said computer system.

3. The memory module according to claim 1 wherein said printed circuit board has a set of pins for conveying electrical signals.

4. The memory module according to claim 3 wherein said printed circuit board includes pins for receiving said first, second, third and fourth chip select signals.

5. The memory module according to claim 3 wherein said printed circuit board includes pins for receiving said first, second, third and fourth clock enable signals.

6. The memory module according to claim 3 wherein said printed circuit board includes pins for receiving control signals comprising at least one column address strobe signal (CAS).

7. The memory module according to claim 3 wherein said printed circuit board includes pins for receiving control signals comprising at least one row address strobe signal (RAS).

8. The memory module according to claim 3 wherein said printed circuit board includes pins for receiving control signals comprising at least one write enable signal (WE).

9. The memory module according to claim 3 wherein said electrical signals include data signals.

10. The memory module according to claim 1 wherein said memory chips include address signals.

11. The memory module according to claim 1 wherein said memory chips are arranged in a single level.

12. The memory module according to claim 1 wherein said memory chips are stacked as chip packages and mounted upon said printed circuit board.

13. A memory module for a computer system comprising:
a plurality of printed circuit boards;
a first, second, third and fourth bank of memory chips mounted upon said set of printed circuit boards;
a first chip select signal and a first clock enable signal routed to said set of printed circuit boards for activating said first bank of memory chips;
a second chip select signal and a second clock enable signal routed to said set of printed circuit boards for activating said second bank of memory chips;
a third chip select signal and a third clock enable signal routed to said set of printed circuit boards, for activating said third bank of memory chips; and
a fourth chip select signal and a fourth clock enable signal routed to said set of printed circuit boards for activating said fourth bank of memory chips.

14. The memory module according to claim 13 wherein said set of printed circuit boards has a connector edge for connecting to said computer system.

15. The memory module according to claim 13 wherein said set of printed circuit boards has a set of pins for conveying electrical signals.

16. The memory module according to claim 15 wherein said set of printed circuit boards includes pins for receiving said first, second, third and fourth chip select signals.

17. The memory module according to claim 15 wherein said set of printed circuit boards includes pins for receiving said first, second, third and fourth clock enable signals.

18. The memory module according to claim 15 wherein said set of printed circuit boards includes pins for receiving control signals comprising at least one column address strobe signal (CAS).

19. The memory module according to claim 15 wherein said set of printed circuit boards includes pins for receiving control signals comprising at least one row address strobe signal (RAS).

20. The memory module according to claim 15 wherein said set of printed circuit boards includes pins for receiving control signals comprising at least one write enable signal (WE).

21. The memory module according to claim 15 wherein said electrical signals include data signals.

22. The memory module according to claim 15 wherein said electrical signals include address signals.

23. The memory module according to claim 13 wherein said memory chips are arranged in a single level.

24. The memory module according to claim 13 wherein said memory chips are stacked as chip packages and mounted upon said set of printed circuit boards.
